(19) United States
(12) Patent Application Publication
(10) Pub. No.: US 2014/0185244 A1
(43) Pub. Date: Jul. 3, 2014

(54) THERMALLY CONDUCTIVE FILM AND CIRCUIT BOARD MODULE

(71) Applicant: SAMSUNG ELECTRO-MECHANICS CO., LTD., Suwon (KR)

(72) Inventors: Jae Sang LEE, Suwon (KR); Ji Hyuk Lim, Suwon (KR); Suk Jin Ham, Suwon (KR)

(73) Assignee: SAMSUNG ELECTRO-MECHANICS CO., LTD., Suwon (KR)

(21) Appl. No.: 13/866,619

(22) Filed: Apr. 19, 2013

(30) Foreign Application Priority Data
Dec. 28, 2012 (KR) 10-2012-0157023

(51) Int. Cl. H05K 1/02; H01B 1/22; H01B 1/24

(52) U.S. Cl. CPC H05K 1/0209; H01B 1/24; H01B 1/22
USPC 361/709; 252/74; 252/73

(57) ABSTRACT

There is provided a circuit board module including a heat radiation member, a thermally conductive film that is disposed on the heat radiation member and includes a thermally conductive filler, a circuit board formed on the thermally conductive film, and a heat generation device disposed on the circuit board, wherein the thermally conductive filler is distributed in an area of the thermally conductive film corresponding to the heat generation device and another area that is extended from the area corresponding to the heat generation device by a predetermined distance on a plane.

### CROSS-REFERENCE TO RELATED APPLICATIONS

This application claims the priority of Korean Patent Application No. 10-2012-0157023 filed on Dec. 28, 2012, in the Korean Intellectual Property Office, the disclosure of which is incorporated herein by reference.

### BACKGROUND OF THE INVENTION

1. Field of the Invention

The present invention relates to a thermally conductive film with improved heat radiation characteristics and a circuit board module.

2. Description of the Related Art

In terms of electronic appliances, while the trend has been for reductions in the size thereof, power consumption cannot be greatly reduced due to a diversity of applications being included therein, and thus, measures for heat dissipation within electronic appliances have been further required.

As heat dissipation measures for an electronic appliance, for example, a heat radiation plate, a heat pipe, or a heat sink formed of a metal having high thermal conductivity, such as copper or aluminum, is widely used. Such heat radiation components which have high thermal conductivity are disposed adjacently to heat generating electronic components such as semiconductor packages and resistors in an electronic appliance in order to improve heat radiation effects or to reduce a temperature of the electronic appliance.

Also, heat radiation components having high thermal conductivity are disposed across a low-temperature spot in an electronic component, a heat generating unit. Also, in order to affix the electronic component and a metal heat radiation component to one another, and to fill a space created during adhesion, a thermally conductive polymer composite sheet is disposed between the electronic component and the metal heat radiation component.

In the case of a semiconductor device, in particular, it is reported that the lifespan of the semiconductor device decreases exponentially with respect to temperature and is reduced by half for every 10° C. increase in operating temperature.

Accordingly, a thermally conductive sheet that allows for more efficient heat radiation is necessary.

The Related Art Document below discloses a thermally conductive sheet, in which a content of a filler varies in a vertical direction, but does not disclose a thermally conductive sheet in which a content of a filler varies in a horizontal direction.

### RELATED ART DOCUMENT

Japanese Patent Laid-Open Publication No. 2004-250674

### SUMMARY OF THE INVENTION

An aspect of the present invention provides a thermally conductive film having improved heat radiation characteristics and a circuit board module.

According to an aspect of the present invention, there is provided a circuit board module including: a heat radiation member; a thermally conductive film that is disposed on the heat radiation member and includes a thermally conductive filler; a circuit board formed on the thermally conductive film; and a heat generation device disposed on the circuit board, wherein the thermally conductive filler is distributed in an area of the thermally conductive film corresponding to the heat generation device and an another area that is extended from the area corresponding to the heat generation device by a predetermined distance on a plane.

When the predetermined distance for which the area is extended from the area corresponding to the heat generation device, in the areas having the thermally conductive filler distributed therein, is a, a thickness of the circuit board is b, and a thickness of the thermally conductive film is c, a may satisfy the inequality: 2(b+c)≦a≦10(b+c).

The thermally conductive filler may include at least one of silica coated aluminum nitride, boron nitride, alumina, and aluminum nitride.

The thermally conductive film may include a first area including both the thermally conductive filler and the adhesive resin and a second area including the adhesive resin and not including the thermally conductive filler.

The thermally conductive film may further include an adhesive resin.

The adhesive resin may include an epoxy resin.

The heat radiation member may include aluminum (Al) or an alloy of Al.

According to another aspect of the present invention, there is provided a thermally conductive film including: an adhesive resin; and a thermally conductive filler, wherein the thermally conductive film is configured of a first area including both the thermally conductive filler and the adhesive resin and a second area including the adhesive resin and not including the thermally conductive filler.

The first and second areas may be disposed such that the second area surrounds the first area on a plane.

The thermally conductive filler may include at least one of silica coated aluminum nitride, boron nitride, alumina, and aluminum nitride.

The adhesive resin may include an epoxy resin.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. The above and other aspects, features and other advantages of the present invention will be more clearly understood from the following detailed description taken in conjunction with the accompanying drawings, in which:

FIG. 1 is a schematic perspective view of a circuit board module according to an embodiment of the present invention;

FIG. 2 is a plan view of the circuit board module of FIG. 1;

FIG. 3 is a cross-sectional view of the circuit board module of FIG. 1 cut along line A-A′;

FIG. 4 is a heat analysis graph showing heat emitted from a heat source, being transferred to a board; and

FIG. 5 is a graph showing a normalized temperature of a lower portion of a thermally conductive film.

### DETAILED DESCRIPTION OF THE EMBODIMENT

Hereinafter, embodiments of the present invention will be described in detail with reference to the accompanying drawings. The invention may, however, be embodied in many different forms and should not be construed as being limited to the embodiments set forth herein.

Rather, these embodiments are provided so that this disclosure will be thorough and complete, and will fully convey the scope of the invention to those skilled in the art.

Hereinafter, a thermally conductive film and a circuit board module according to the embodiments of the present invention will be described with reference to the accompanying drawings.

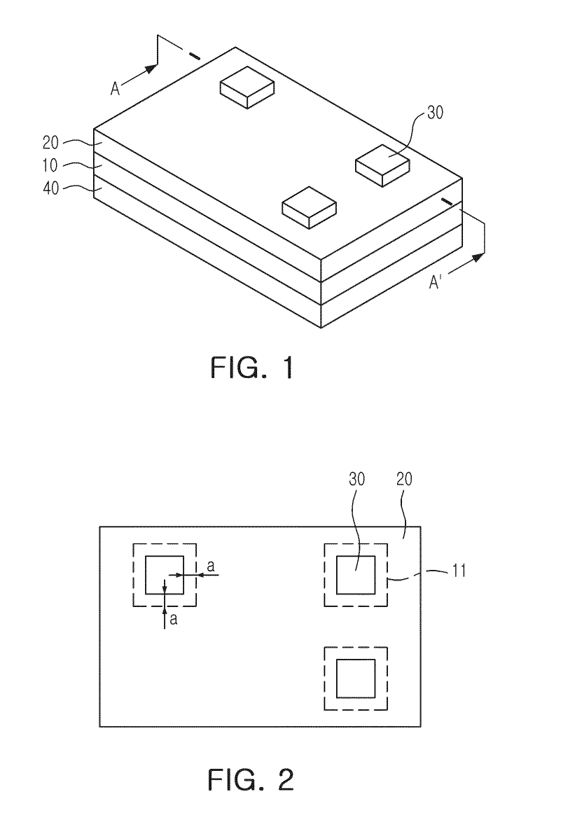

FIG. 1 is a schematic perspective view of a circuit board module according to an embodiment of the present invention.

FIG. 2 is a plan view of the circuit board module of FIG. 1.

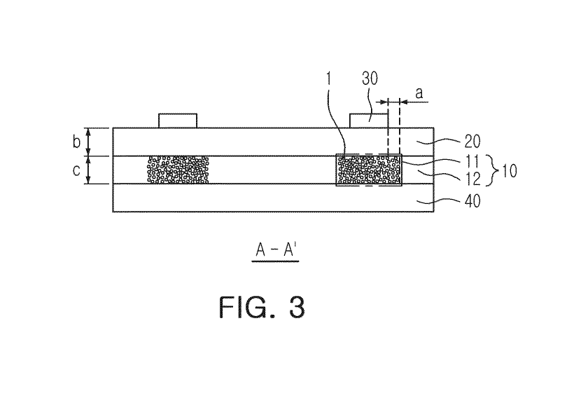

FIG. 3 is a cross-sectional view of the circuit board module of FIG. 1 cut along line A-A′.

Referring to FIGS. 1 through 3, the circuit board module according to the embodiment of the present invention may include a heat radiation member 40, a thermally conductive film 10, a circuit board 20, and a heat generation device 30.

Various components may be mounted on the circuit board 20, and a printed circuit board will be described as an example of the circuit board 20 according to the embodiment of the present invention.

The heat generation device 30 is disposed on the circuit board 20, and the heat generation device 30 may be, for example, a light emitting diode package or a resistor, but is not limited thereto.

The thermally conductive film 10 is disposed below the circuit board 20 on which the heat generation device 30 is disposed, and the heat radiation member 40 is disposed below the thermally conductive film 10. That is, the thermally conductive film 10 may be disposed between the circuit board 20 and the heat radiation member 40.

The thermally conductive film 10 may include a polymer resin and a thermally conductive filler 1. A polymer resin used as an insulating material in a circuit board module generally has relatively low thermal conductivity, and thus is very vulnerable with respect to heat radiation. Thus, to solve this problem, a high thermal conductivity filler is added.

A method to increase thermal conductivity of a film containing a polymer resin and a thermally conductive filler is to significantly increase the content of a filler having high conductivity.

That is, a smooth heat transfer is induced through a high thermal conductivity filler by increasing a volumetric ratio of the filler. Here, heat radiation characteristics of a film are determined by thermal conductivities of a polymer resin and a filler and a volumetric ratio of the filler.

According to the related art, a thermally conductive filler and a polymer resin are mixed with each other and are uniformly distributed in a thickness direction of a thermally conductive film thereinside and in a direction to a plane perpendicular to the thickness of the thermally conductive film. However, according to the embodiment of the present invention, the thermally conductive filler is locally distributed in the thermally conductive film.

That is, the thermally conductive film 10 according to the embodiment of the present invention maybe classified into a first area 11 including a thermally conductive filler and a second area 12 not including a thermally conductive filler.

The first area 11 may include a thermally conductive filler and an adhesive resin, and the second area 12 may include an adhesive resin but may not include a thermally conductive filler.

In the thermally conductive film 10, the first area 11 may substantially secure thermal conductivity, and the second area 12 may improve adhesive properties.

When a thermally conductive filler is included entirely in the thermally conductive film 10, there is limitation in terms of an increase in a volumetric ratio of the thermally conductive filler for securing adhesive properties of the film.

However, in the embodiment of the present invention, when the thermally conductive film 10 includes the first area 11 including a thermally conductive filler and the second area 12 not including a thermally conductive filler, the adhesive properties may be provided by the second area 12, and accordingly, the amount of the thermally conductive filler included in the first area 11 may be further increased as compared to the related art.

The first area 11 may include an area corresponding to the heat generation device 30 in the thermally conductive film 10 and another area that is extended from the above area by a predetermined distance along a plane.

As illustrated in FIGS. 2 and 3, when a predetermined distance for which the area is extended on a plane, that is, horizontally, from the area corresponding to the heat generation device 30, in the first area 11 having the thermally conductive filler 1 distributed therein, is a, a thickness of the circuit board is b, and a thickness of the thermally conductive film is c, a may satisfy the inequality: 2(b+c)≦a≦10(b+c).

In the embodiments of the present invention, “on a plane” may refer to a location on a plane that is formed by a set of directions perpendicular to stacking directions of the heat radiation member 40, the thermally conductive film 10, and the circuit board 20.

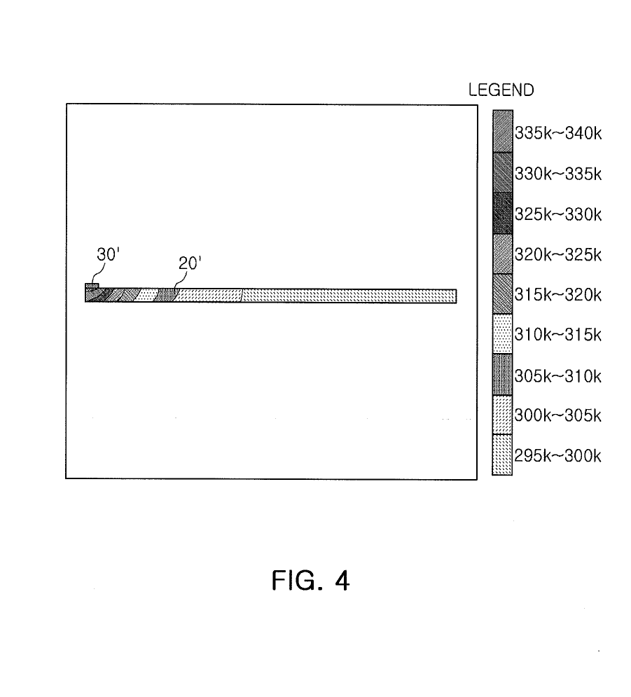

FIG. 4 is a heat analysis graph showing heat emitted from a heat source 30′ disposed on a circuit board 20′, transferred to the circuit board 20′, according to another embodiment of the present invention. A horizontally extended bar in the graph denotes a cross-section of the circuit board 20′, and it is shown that the heat source 30′ is disposed on an upper left portion of the circuit board 20′.

When regarding the heat generation device 30 as a heat source, heat is transferred from the heat source 30′ in all directions. As heat generated in the heat source 30′ is spread not only in a perpendicular direction but in all directions, that is, in radial directions as illustrated in FIG. 4, in order to efficiently transfer the heat generated in the heat generation device 30 to the heat radiation member 40, the first area 11 needs to be formed to have a larger area than the area corresponding to the heat generation device 30.

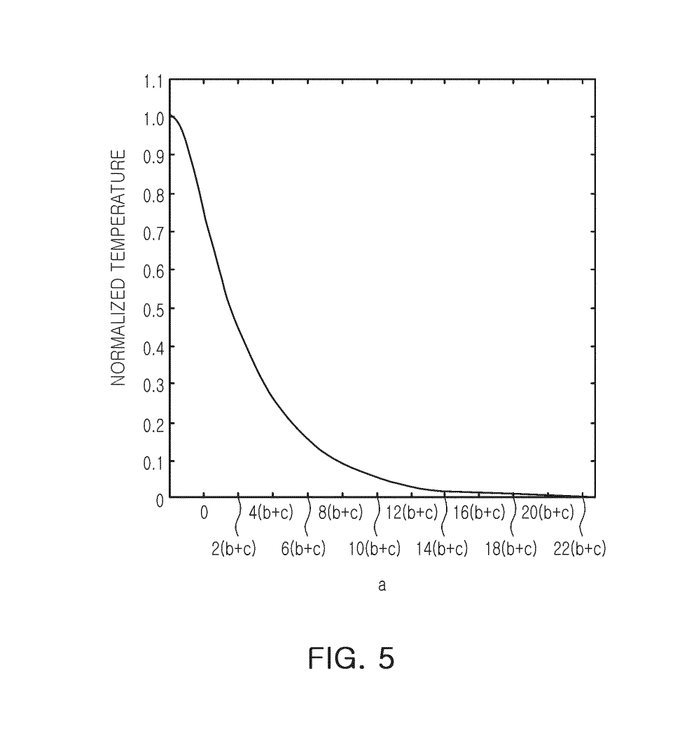

FIG. 5 is a graph showing a temperature of a lower surface of a thermally conductive film, an opposite surface to a surface of the thermally conductive film contacting a circuit board after disposing the thermally conductive film in which a thermally conductive filler is uniformly dispersed, below the circuit board on which a heat generation device is disposed, unlike the embodiment of the present invention.

In detail, FIG. 5 shows a temperature ratio of respective locations on a lower surface of the thermally conductive film with respect to a relatively highest temperature. That is, the temperature with respect to the locations that is normalized by denoting an x-axis as ‘a’ and a y-axis as ‘a ratio of a temperature at ‘a’ to the highest temperature on the lower surface of the thermally conductive film’ is shown.

As shown in FIG. 5, the temperature of the lower surface of the thermally conductive film around a heat source is relatively high. In other words, it can be seen from the temperature interpretation graph that heat transfer is concentrated on a portion around the heat source, and the influence of the heat source on a board and a thermally conductive film that are spaced apart from the heat source is relatively low.

In particular, when a is less than 2(b+c), a normalized temperature has a value of about 0.5 or higher. That is, since a considerable amount of heat generated in the heat source can be regarded as having been transferred when a temperature of a lower portion of the thermally conductive film is reduced to the half of an initial temperature, a may be equal to or greater than 2(b+c).

In addition, when a exceeds 10(b+c), a normalized temperature is less than 0.05, and thus, it can be seen that a substantial heat transfer does not occur in a section in which a exceeds 10(b+c).

Consequently, it can be concluded that in order to reduce the production costs by reduction in the content of a filler and to increase the heat transfer effects, a may satisfy the inequality of 2(b+c)≦a≦10(b+c).

The thermally conductive filler 1 may include at least one of silica coated aluminum nitride, boron nitride, alumina, and aluminum nitride, but is not limited thereto, and any material having high thermal conductivity may be used without limitation.

Furthermore, a polymer resin included in a thermally conductive film may be an adhesive resin having adhesive properties to increase adhesive force with respect to a circuit board and a heat radiation member, and may include, without limitation, an epoxy resin.

Moreover, examples of the epoxy resin may include, without limitation, a phenol novolac type epoxy resin, a Kresol novolac type epoxy resin, a bisphenol A type epoxy resin, a bisphenol F type epoxy resin, a bisphenol S type epoxy resin, a biphenyl type epoxy resin, a biphenyl novolac type epoxy resin, a tris-hydroxyphenyl methane type epoxy resin, a tetra phenyl ethane type epoxy resin, a dicyclo pentadiene phenol type epoxy resin, an epoxy resin of a hydrogen-added compound of an aromatic bisphenol compound or a polyphenol compound, a cycloaliphatic epoxy resin such as cyclohexene oxide, a glycidyl amine type epoxy, and a mixture thereof.

Furthermore, to provide good moldability characteristics, the thermally conductive film 10 may further include a phenoxy resin.

In addition, for hardening of a resin, the thermally conductive film 10 may further include a hardening agent.

To locally dispose the thermally conductive filler 1 in a polymer resin in the first area 11, a method of only coating a thermally conductive filler in a required area by using an inkjet ejection method may be used, or a method, in which a magnetic field is generated on and below a mixture of an unhardened polymer resin and a thermally conductive filler so that the thermally conductive filler 1 is concentrated on a particular portion, may be used.

Furthermore, the first area 11 and the second area 12 may be separated from each other in a planar manner. In other words, the first area 11 and the second area 12 may not be divided but either the first area 11 or the second area 12 may present in a stacking direction of the heat radiation member 40, the thermally conductive film 10, and the circuit board 20 (hereinafter referred to as a stacking direction). However, the thermally conductive film 10 maybe divided into the first area 11 and the second area 12 in a direction perpendicular to the stacking direction.

In addition, in the thermally conductive film 10 according to the embodiment of the present invention, the first area 11 and the second area 12 may be disposed such that the second area 12 surrounds the first area 11 on a plane that is perpendicular to the stacking direction so as to prevent a decrease in adhesive force between the circuit board 20 and the heat radiation member 40 due to the first area 11 having a relatively low resin content.

The heat radiation member 40 is disposed below the thermally conductive film 10 and is adhered to the circuit board 20 via the thermally conductive film 10.

The heat radiation member 40 may include, without limitation, aluminum (Al), and may perform the function of radiating heat generated in the heat generation device 30 such as a resistor mounted on the circuit board 20.

According to the embodiments of the present invention, an amount of a thermally conductive filler included in an area (the first area 11) in which heat transfer occurs in a thermally conductive film may be increased to thereby increase heat radiation efficiency, and the content of a polymer resin is increased in an area (the second area 12) in which heat transfer is substantially not generated. Accordingly, sufficient adhesive force between the thermally conductive film, the heat radiation member, and the circuit board may be provided.

Furthermore, the entire content of the thermally conductive filler in the thermally conductive film, a relatively expensive raw material, may be reduced, thereby reducing the production costs.

Also, the content of a polymer resin included in the entire thermally conductive film may be increased, and thus, a circuit board module resistant to stress and bending impacts may be obtained.

As set forth above, according to the embodiments of the present invention, an amount of a thermally conductive filler contained in an area of a thermally conductive film in which heat transfer is generated may be increased so as to improve heat radiation efficiency, and a sufficient adhesive force between the thermally conductive film, the heat radiation member, and the circuit board may be secured.

Furthermore, the total content of the thermally conductive filler, a relatively expensive raw material, in the thermally conductive film may be reduced, thereby reducing production costs.

In addition, the content of a polymer resin included in the entire thermally conductive film may be increased, and thus, a circuit board module resistant to stress and bending impacts may be obtained.

While the present invention has been shown and described in connection with the embodiments, it will be apparent to those skilled in the art that modifications and variations can be made without departing from the spirit and scope of the invention as defined by the appended claims. For example, a resistor pad in the embodiments of the present invention may be formed on the entire lower surface of a resistor, or on a portion of a lower surface of the resistor.

While the present invention has been shown and described in connection with the embodiments, it will be apparent to those skilled in the art that modifications and variations can be made without departing from the spirit and scope of the invention as defined by the appended claims.

What is claimed is:

1. A circuit board module comprising:
a heat radiation member;
a thermally conductive film that is disposed on the heat radiation member and includes a thermally conductive filler;
a circuit board formed on the thermally conductive film; and
a heat generation device disposed on the circuit board,
wherein the thermally conductive filler is distributed in an area of the thermally conductive film corresponding to the heat generation device and another area that is extended from the area corresponding to the heat generation device by a predetermined distance on a plane.

2. The circuit board module of claim 1, wherein when the predetermined distance for which the area is extended from the area corresponding to the heat generation device, in the areas having the thermally conductive filler distributed therein, is a, a thickness of the circuit board is b, and a thickness of the thermally conductive film is c, a satisfies the inequality: 2(b+c)≦a≦10(b+c).

3. The circuit board module of claim 1, wherein the thermally conductive filler includes at least one of silica coated aluminum nitride, boron nitride, alumina, and aluminum nitride.

4. The circuit board module of claim 1, wherein the thermally conductive film includes a first area including both the thermally conductive filler and an adhesive resin and a second area including the adhesive resin and not including the thermally conductive filler.

5. The circuit board module of claim 1, wherein the thermally conductive film further includes an adhesive resin.

6. The circuit board module of claim 5, wherein the adhesive resin includes an epoxy resin.

7. The circuit board module of claim 1, wherein the heat radiation member includes aluminum (Al) or an alloy of Al.

8. A thermally conductive film comprising:
an adhesive resin; and
a thermally conductive filler,
wherein the thermally conductive film is configured of a first area including both the thermally conductive filler and the adhesive resin and a second area including the adhesive resin and not including the thermally conductive filler.

9. The thermally conductive film of claim 8, wherein the first and second areas are disposed such that the second area surrounds the first area on a plane.

10. The thermally conductive film of claim 8, wherein the thermally conductive filler includes at least one of silica coated aluminum nitride, boron nitride, alumina, and aluminum nitride.

11. The thermally conductive film of claim 8, wherein the adhesive resin includes an epoxy resin.
